(19) United States
(12) Patent Application Publication
(10) Pub. No.: US 2020/0035513 A1
(43) Pub. Date: Jan. 30, 2020

(54) PROCESSING APPARATUS

(71) Applicant: Applied Materials, Inc., Santa Clara, CA (US)

(72) Inventors: Adib KHAN, Cupertino, CA (US); Qiwei LIANG, Fremont, CA (US); Sultan MALIK, Sacramento, CA (US); Srinivas D. NEMANI, Sunnyvale, CA (US)

(21) Appl. No.: 16/510,848

(22) Filed: Jul. 12, 2019

Related U.S. Application Data
(60) Provisional application No. 62/703,243, filed on Jul. 25, 2018.

(51) Int. Cl. H01L 21/67; F01K 1/00

(52) U.S. Cl. CPC H01L 21/67017; F01K 1/00

(57) ABSTRACT

The present disclosure relates to high pressure processing apparatus for semiconductor processing. The apparatus described herein include a high pressure process chamber and a containment chamber surrounding the process chamber. A steam delivery module is in fluid communication with the high pressure process chamber and is configured to deliver steam to the process chamber. The steam delivery module includes a boiler and a steam reservoir.

### CROSS-REFERENCE TO RELATED APPLICATIONS

This application claims benefit of U.S. Provisional Patent Application No. 62/703,243, filed Jul. 25, 2018, the entirety of which is hereby incorporated by reference.

### BACKGROUND

### Field

Embodiments of the present disclosure generally relate to apparatus for semiconductor processing. More specifically, embodiments of the disclosure relate to high pressure processing apparatus.

### Description of the Related Art

The field of semiconductor manufacturing utilizes various processes to fabricate devices which are incorporated into integrated circuits. As device complexity increases, integrated circuit manufacturers look for improved methodologies to fabricate advanced node devices. For example, advanced processing characteristics may include the utilization of more extreme process variables to enable advanced device fabrication.

One example of a process variable which is increasingly being investigated for utilization in semiconductor manufacturing is high pressure processing. High pressure processing at pressures elevated above atmospheric pressure has shown promising material modulation characteristics. However, apparatus suitable for safely and efficiently performing high pressure processing is often lacking when considering the requisite degree of control desired to perform advanced node device fabrication processes.

Accordingly, what is needed in the art are improved high pressure processing apparatus and methods for performing high pressure processing.

### SUMMARY

In one embodiment, a high pressure processing apparatus is provided. The apparatus includes a first chamber body defining a first volume therein and a second chamber body disposed within the first volume. The second chamber body defines a second volume therein and a steam delivery module is in fluid communication with the second volume via a first conduit. The steam delivery module includes a boiler, a steam reservoir, a second conduit extending between and in fluid communication with the boiler and the steam reservoir, and a flow regulator disposed on the second conduit between the boiler and the steam reservoir.

In another embodiment, a high pressure processing apparatus is provided. The apparatus includes an enclosure defining a volume therein, a boiler disposed in the volume, and a steam reservoir disposed in the volume. The boiler includes a fluid inlet port, a fluid outlet port, and an exhaust port. The steam reservoir includes a fluid inlet port, a fluid outlet port, and an exhaust port. A conduit extends between the boiler fluid outlet port and the steam reservoir inlet port and a flow regulator is disposed on the conduit between the boiler and the steam reservoir.

In yet another embodiment, a high pressure processing apparatus is provided. The apparatus includes a first chamber body defining a first volume therein, a first slit valve door coupled to an external surface of the first chamber body, and a second chamber body disposed within the first volume. The second chamber body defines a second volume therein and a second slit valve door is coupled to an interior surface of the second chamber body. A steam delivery module is in fluid communication with the second volume via a first conduit and the steam delivery module includes a boiler fabricated from a nickel containing steel alloy and a steam reservoir fabricated from the nickel containing steel alloy.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic illustration of a high pressure processing apparatus according to an embodiment described herein.

FIG. 2 is a schematic illustration of a steam delivery module according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to high pressure processing apparatus for semiconductor processing. The apparatus described herein include a high pressure process chamber and a containment chamber surrounding the process chamber. A steam delivery module is in fluid communication with the high pressure process chamber and is configured to deliver steam to the process chamber. The steam delivery module includes a boiler and a steam reservoir.

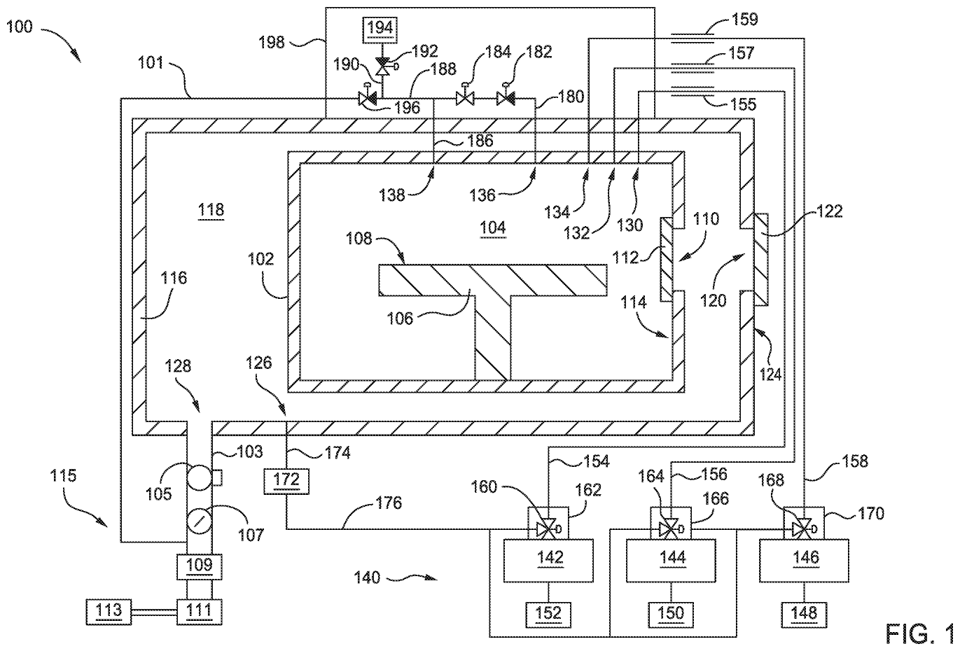

FIG. 1 is a schematic illustration of a high pressure processing apparatus 100 according to an embodiment described herein. The apparatus 100 includes a first chamber 116 which defines a first volume 118 therein. In one embodiment, a volume of the first volume 118 is between about 80 liters and about 150 liters, for example, between about 100 liters and about 120 liters. The first chamber 116 is fabricated from a process compatible material, such as aluminum, stainless steel, alloys thereof, and combinations thereof. The material selected for fabrication of the first chamber 116 is suitable for operation at sub-atmospheric pressures, for example pressures less than about 700 Torr, such as 650 Torr or less.

The first chamber 116 has an exhaust port 128 formed therein. An exhaust conduit 103 is coupled to the first chamber 116 at the exhaust port 128 such that the exhaust conduit 103 is in fluid communication with the first volume 118. An isolation valve 105 and a throttle valve 107 are disposed on the exhaust conduit 103. The isolation valve 105 is disposed on the exhaust conduit 103 between the throttle valve 107 and the exhaust port 128. The isolation valve 105 is operable to initiate and extinguish fluid communication between the first volume 118 and an exhaust 113. The throttle valve 107 controls a flow rate of effluent flowing through the exhaust conduit 103 from the first volume 118.

A pump 109 is also coupled to the exhaust conduit 103 and the pump 109 operates to pull fluid from the first volume 118 to the exhaust 113. The pump 109 is disposed on exhaust conduit 103 between the throttle valve 107 and the exhaust 113. In one embodiment, the pump 109 generates a sub-atmospheric pressure in the first volume 118, such as a pressure less than about 700 Torr. A scrubber 111 is also disposed on the exhaust conduit 103 between the pump 109 and the exhaust 113. The scrubber 111 is in fluid communication with the first volume 118 via the exhaust conduit 103 and the scrubber 111 is configured to treat effluent from the first volume 118 prior to the effluent exiting the exhaust conduit 103 to the exhaust 113.

The first chamber 116 has an external surface 124 which is not exposed to the first volume 118. A first slit valve 120 is formed in the chamber 116 to enable ingress and egress of a substrate therethrough. A first slit valve door 122 is coupled to the external surface 124 adjacent to the first slit valve 120. In operation, the first slit valve door 122 is opened to enable passage of the substrate therethrough and closes prior to processing of the substrate.

A second chamber 102 is disposed within the first volume 118 defined by the first chamber 116. The second chamber 102 defines a second volume 104 therein. Similar to the first chamber 116, the second chamber 102 is fabricated from a process compatible material, such as aluminum, stainless steel, alloys thereof, and combinations thereof. In one embodiment, the second chamber 102 is fabricated from a nickel containing steel alloy, for example, a nickel molybdenum containing steel alloy or a nickel chromium molybdenum containing steel alloy. The material selected for fabrication of the second chamber 102 is suitable for operation of the second volume 104 at high pressures, such as greater than about 30 bar, for example, about 50 bar or greater.

A pedestal 106 is disposed in the second chamber 102 and the pedestal 106 has a substrate support surface 108 for supporting a substrate thereon during processing. In one embodiment, the pedestal 106 includes a resistive heater operable of maintaining a temperature of a substrate disposed on the substrate support surface 108 at a temperature of up to about 550° C. Although not illustrated, a stem of the pedestal 106 extends through the second chamber 102 and the first chamber 116. The stem of the pedestal 106 may be isolated from the first volume 118 by a bellows assembly which is operable isolate the pedestal 106 from the first volume 118.

A second slit valve 110 is formed through the second chamber 102 to enable ingress and egress of the substrate therethrough. The second slit valve 110 is substantially aligned in approximately the same plane as the first slit valve 120. A second slit valve door 112 is coupled to an internal surface 114 of the second chamber 102 adjacent to the second slit valve 110. The positioning of the second slit valve door 112 on the internal surface 114 enables more secure sealing of the second volume 104 during high pressure processing because the high pressure maintained within the second volume 104 urges the second slit valve door 112 against the internal surface 114 to create a substantially air tight seal. In operation, the second slit valve door 112 is opened to enable passage of the substrate from the first slit valve 120. After the substrate is positioned on the substrate support surface 108 of the pedestal 106, the second slit valve door 112 closes prior to processing of the substrate.

A fluid management apparatus 140 is configured to deliver one or more fluids to the second volume 104 of the second chamber 102. The fluid management apparatus 140 includes a first fluid delivery module 144, a second fluid delivery module 142, and a third fluid delivery module 146. The first fluid delivery module 144 is operable to generate steam and deliver steam to the second volume 104. The first fluid delivery module 144 is in fluid communication with a first fluid source 150. In one embodiment, the first fluid source 150 is a water source, and more specifically, a deionized water source. The second fluid delivery module 142 is in fluid communication with a second fluid source 152. In one embodiment, the second fluid source 152 is a hydrogen source, and more specifically, an H₂ source. The third fluid delivery module 146 is in fluid communication with a third fluid source 148. In one embodiment, the third fluid source 148 is a nitrogen gas source, for example, an ammonia source.

The first fluid delivery module 144 is in fluid communication with the second volume 104 via a first conduit 156. A valve 164 is disposed between the first fluid delivery module 144 and the first conduit 156. The valve 164 is operable to enable fluid flow from the first fluid delivery module 144 through the first conduit 156. A containment enclosure 166 surrounds the valve 164 and the connections of the valve 164 between the first fluid delivery module 144 and the first conduit 156. The first conduit 156 extends from the first valve 164 through the first chamber 116, the first volume 118, and the second chamber 102 to a port 132 formed on the internal surface 114 of the second chamber 102. In one embodiment, a heater jacket 157 surrounds the first conduit 156 and extends along a length of the first conduit 156 between the valve 164 and the first chamber 116.

The second fluid delivery module 142 is in fluid communication with the second volume 104 via a second conduit 154. A valve 160 is disposed between the second fluid delivery module 142 and the second conduit 154. The valve 160 is operable to enable fluid flow from the second fluid delivery module 142 through the second conduit 154. A containment enclosure 162 surrounds the valve 160 and the connections of the valve 160 between the second fluid delivery module 142 and the second conduit 154. The second conduit 154 extends from the second valve 160 through the first chamber 116, the first volume 118, and the second chamber 102 to a port 130 formed on the internal surface 114 of the second chamber 102. In one embodiment, a heater jacket 155 surrounds the second conduit 154 and extends along a length of the second conduit 154 between the valve 160 and the first chamber 116.

The third fluid delivery module 146 is in fluid communication with the second volume 104 via a third conduit 158. A valve 168 is disposed between the third fluid delivery module 146 and the third conduit 158. The valve 168 is operable to enable fluid flow from the third fluid delivery module 146 through the third conduit 158. A containment enclosure 170 surrounds the valve 168 and the connections of the valve 168 between the third fluid delivery module 146 and the third conduit 158. The third conduit 158 extends from the third valve 168 through the first chamber 116, the first volume 118, and the second chamber 102 to a port 134 formed on the internal surface 114 of the second chamber 102. In one embodiment, a heater jacket 159 surrounds the third conduit 158 and extends along a length of the third conduit 158 between the valve 168 and the first chamber 116.

Each of the heater jackets 155, 157, 159 are operable to maintain a temperature of a respective conduit 154, 156, 158 at about 300° C. or greater, for example, about 350° C. or higher. In one embodiment the heater jackets 155, 157, 159 comprise resistive heaters. In another embodiment, the heater jackets 155, 157, 159 comprise fluid channels though which a heated fluid is flowed. By maintaining the conduits 154, 156, 158 at elevated temperatures, steam and other high pressure fluids maintain desirable property characteristics during transfer from the respective fluid delivery modules 142, 144, 146 to the second volume 104. In one example, steam generated in the fluid delivery module 144 is maintained in the conduit 156 at elevated temperatures by the heater jacket 157 to prevent or substantially reduce the probability of condensation during steam transfer.

The apparatus 100 also includes a purge gas source 172. In one embodiment, the purge gas source 172 is an inert gas source, such as a nitrogen source or a noble gas source. The purge gas source 172 is in fluid communication with the first volume 118. A conduit 174 extends from the purge gas source 172 to a port 126 formed in the first chamber 116. The fluid communication between the purge gas source 172 and the first volume 118 enables the first volume 118 to be purged with an inert gas. It is contemplated that the first volume 118 is a containment volume that functions as a failsafe should the second volume 104 experience an unplanned depressurization event. By having a sufficiently large volume to function as an expansion volume and by having purge gas capability, the first volume 118 enables improved safety of operation of the second chamber 102 at elevated pressures.

The purge gas source 172 is also in fluid communication with each of the conduits 156, 154, 158. A conduit 176 extends from the purge gas source 172 to each of the valves 160, 164, 168. When the valves 160, 164, 168 are opened to receive purge gas from the purge gas source 172 flowing through the conduit 176, the conduits 154, 156, 158 are purged to eliminate fluids in the conduits 154, 156, 158 that were previously delivered from the fluid delivery modules 142, 144, 146. The fluid communication between the purge gas source 172 and the conduits 154, 156, 158 also enables purging of the second volume 104.

To remove fluids from the second volume 104, an exhaust port 136 is formed in the second chamber 102. A conduit 180 extends from the exhaust port 136 to a regulator valve 184 which is configured to enable a pressure drop across the regulator valve 184. In one embodiment, pressurized fluid exhausted from the second volume 104 travels through the exhaust port 136, through the conduit 180, and through a valve 182 to the regulator valve 184 where a pressure of the fluid is reduced from greater than about 30 bar, such as about 50 bar, to between about 0.5 bar to about 3 bar. The valve 182 is disposed inline with the regulator valve 184 and enables transfer of the reduced pressure fluid from the conduit 180 to a conduit 188.

A pressure relief port 138 is also formed in the second chamber 102. A conduit 186 extends from the pressure relief port 138 to the conduit 188 and the conduit 186 is coupled to the conduit 188 downstream of the regulator valve 184 and the valve 182. The pressure relief port 138 and conduit 186 are configured to bypass the regulator valve 184 and function as a secondary pressure reduction for the second volume 104. A valve 196 is disposed on the conduit 188 downstream from the conduit 186, the regulator valve 184, and the valve 182. The valve 196 functions to enable fluid flow from the second volume 104 via the pressure relief port 138 without passing through the regulator valve 184. Accordingly, the second volume 104 has a bifurcated pressure relief architecture, first through the exhaust port 136, the conduit 180, and the regulator valve 184, and second, through the pressure relief port 138 and the conduit 186. It is believed that the bifurcated pressure relief architecture enables improved control of the pressures generated in the second volume 104.

A conduit 190 is coupled to and extends from the conduit 188 between the valve 184 and the valve 196. More specifically, the conduit 190 is coupled to the conduit 188 downstream of a location where the conduit 186 is coupled to the conduit 188. A valve 192 is disposed on the conduit 190 and is operable to enable selective fluid communication between the second volume 104 and a steam trap 194. The steam trap 194 is configured to condense steam released from the second volume 104 when high pressure steam processes are performed in the second volume 104. In one embodiment, the steam trap 194 is in fluid communication with the second volume 104 via the conduits 190, 188, and 186 when the valve 192 is opened and the valve 182 is closed. The steam trap 194 may also function as a secondary pressure reduction apparatus for high pressure steam released from the second volume 104.

A containment enclosure 198 is coupled to the first chamber 116 and each of the regulator valve 184, the valve 182, the valve 196, and the valve 192 are disposed within the containment enclosure 198. The conduits 188, 190 are disposed within the containment enclosure 198 and at least a portion of each of the conduits 180, 186 is disposed within the containment enclosure 198. In one embodiment, the steam trap 194 is disposed within the containment enclosure 198. In another embodiment, the steam trap 194 is disposed outside of the containment enclosure 198. The containment enclosure 198 is configured to isolate and contain any leakage of effluent exhausted from the second volume 104. Although not illustrated, the containment enclosure 198 volume is in fluid communication with the scrubber 111 to enable treatment of effluent constrained within the containment enclosure 198.

When the valve 196 is opened, fluid from the conduit 188 travels to a conduit 101 which is in fluid communication with the exhaust conduit 103. The conduit 101 extends form the valve 196 to the exhaust conduit 103 and couples to the exhaust conduit 103 between the throttle valve 107 and the pump 109. Thus, fluid from the second volume 104 which travels through the conduit 101 enters the exhaust conduit 103 upstream from the pump 109 and is subsequently treated by the scrubber 111 prior to exiting to the exhaust 113.

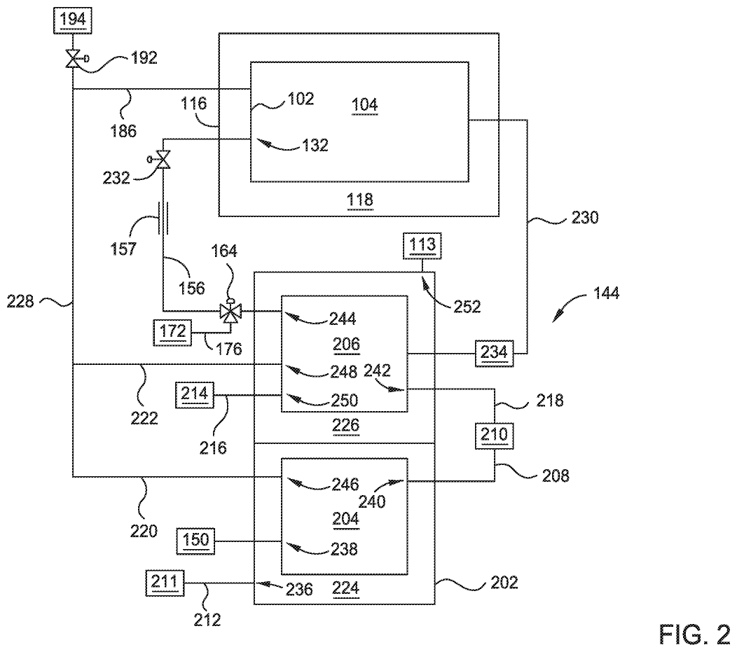

FIG. 2 is a schematic illustration of the fluid delivery module 144 according to an embodiment described herein. In one embodiment, the fluid delivery module 144 is configured to generate, pressurize, and deliver steam to the second volume 104. The fluid delivery module 144 includes a boiler 204 and a reservoir 206. In one embodiment, the boiler 204 is configured to generate steam therein and the reservoir 206 is configured to hold steam in a pressurized state therein prior to delivery of the steam to the second volume 104.

In one embodiment, the boiler 204 and the reservoir 206 are fabricated from similar materials. For example, the boiler 204 and the reservoir 206 are fabricated from a nickel containing steel alloy. In one embodiment, the boiler 204 and the reservoir 206 are fabricated from a nickel containing steel alloy comprising molybdenum. In another embodiment, the boiler 204 and the reservoir 206 are fabricate from a nickel containing steel alloy comprising chromium. The materials selected for the boiler 204 and the reservoir 206 are highly corrosion resistant to enable the generation and maintenance of steam (water vapor) therein, respectively. The materials selected for the boiler 204 and the reservoir 206 are also contemplated to provide sufficient mechanical integrity to enable generation and maintenance of pressures therein at greater than about 30 bar, for example, up to about 240 bar. The boiler 204 and the reservoir 206 are also operable at temperatures greater than about 300° C., such as temperatures greater than about 350° C., for example, temperatures up to about 450° C.

The fluid delivery module 144 includes a containment structure 202. In one embodiment, the boiler 204 and the reservoir 206 are disposed within the containment structure 202 in a single volume. In another embodiment, the containment structure 202 is divided to form separate regions therein, for example, a first region 224 and a second region 226. In one embodiment, the boiler 204 is disposed in the first region 224 and the reservoir 206 is disposed in the second region 226. It is contemplated that the regions 224, 226 may either be in fluid communication with one another or may be fluidly isolated from one another, depending upon the containment characteristics desired.

A purge gas source 211 is coupled to a conduit 212 which extends between the purge gas source 211 to a port 236 formed in the containment structure 202. The port 236 is formed in the containment structure 202 adjacent to the first region 224. In one embodiment, the purge gas source 211 is operable to deliver a purge gas, such an N₂ or a noble gas, to the first region 224. In one embodiment, the first region 224 and the second region 226 are in fluid communication with one another and the purge gas source 211 is operable to deliver a purge gas to both the first region 224 and the second region 226. In another embodiment, the purge gas source 211 is in fluid communication with the boiler 204. The conduit 212 may be coupled directly or indirectly to the port 238 to enable fluid communication between the purge gas source 211 and the boiler 204. In this embodiment, the purge gas source 211 is operable to deliver an inert gas to the boiler 204 to purge the boiler 204 and remove effluent therefrom. Purge gas from the boiler 204 may also be utilized to flush the conduits 208, 218.

The exhaust 113 is in fluid communication with the second region 226 of the containment structure 202 via a port 252 formed in the containment structure 202 adjacent to the second region 226. In one embodiment, fluids existing in the second region 226 outside of the reservoir 206 are exhausted from the second region 226 to the exhaust 113. In embodiments where the first region 224 and the second region 226 are in fluid communication with one another, fluids from both the first region 224 and the second region 226 are capable of being removed from the regions 224, 226 by the exhaust 113.

The fluid source 150 is coupled to and in fluid communication with a port 238 formed in the boiler 204. In one embodiment, the fluid source 150 is operable to deliver deionized water to the boiler 204. The boiler 204 has a port 240 formed therein which is coupled to a conduit 208. The conduit 208 extends to a flow rate controller 210. A conduit 218 extends from the flow rate controller 210 to a port 242 formed in the reservoir 206. The flow rate controller 210 is operable to control a flow rate of steam generated in the boiler 204 and delivered to the reservoir 206 via the conduits 208, 218. A port 246 is also formed in the boiler 204. A conduit 220 is coupled to the port 246. The conduit 220 extends from the port 246 to a conduit 228. The conduit 228 extends between the conduit 220 and the valve 192 which is operable to enable fluid communication between the boiler and the steam trap 194 via the conduits 228, 220. Thus, the port 246 functions as a pressure relief port when the valve 192 is opened to reduce a pressure within the boiler 204.

A port 244 is formed in the reservoir 206. The port 244 is in fluid communication with the conduit 156. A valve 232 is disposed on the conduit 156 which selectively enables fluid communication between the reservoir 206 and the second volume 104. A port 248 is also formed in the reservoir 206. A conduit 222 is coupled to the port 248. The conduit 222 extends from the port 248 to the conduit 228. Similar to pressure relief for the boiler 204, pressure relief for the reservoir 206 is enabled by operation of the valve 192 to enable fluid communication between the reservoir 206 and the steam trap 194 for steam not delivered to the second volume 104. A port 250 is also formed in the reservoir 206. A conduit 216 is coupled to the port 250 and extends between the port 250 and a purge gas source 214. The purge gas source 214 enables purging of the reservoir 206 with an inert gas, such as N₂ or noble gases.

In operation, steam is generated in the boiler 204 by application of heat applied to water disposed in the boiler 204. Steam generated in the boiler 204 is transferred from the boiler 204 to the reservoir 206 at a rate controlled by the flow rate controller 210. The reservoir 206 functions as a pressure vessel to hold the steam in a pressurized state until the steam is delivered to the second volume 104. A controller 234 is in fluid communication between the reservoir 206 and the second volume 104 via the port 130. The controller 234 measures a pressure within the second volume 104 and determines whether more or less steam is needed in the second volume 104 to maintain a set pressure point or range of pressure. The controller 234 is also in communication with one or both of the valve 164 and the valve 232 to facilitate steam delivery to the second volume 104. Thus, the controller 234 provides for closed loop control to enable maintenance of a desired process pressure within the second volume 104.

It is contemplated that the controller 234 is also in communication with the flow rate controller 210 to enable fluid flow between the boiler 204 and the reservoir 206. For example, the controller 234 is in operable communication with the flow rate controller 210 and causes steam generated in the boiler 204 to be transferred to the reservoir 206. When the controller 234 determines that additional steam is warranted in the reservoir 206 to maintain a process pressure of the second volume 104, the controller 234 may also cause the boiler 204 to generate additional steam to re-supply to the reservoir 206.

In summation, apparatus for high pressure processing are described herein. Fluid delivery modules enable generation of fluids at high pressure, such as steam, and facilitate delivery of such fluids to a volume of a process chamber. In one embodiment, the fluid delivery module for steam generation and delivery includes a boiler and a reservoir fabricated from corrosion resistant materials. The boiler and reservoir are in communication with one another to enable generation and maintenance of a sufficient volume of steam for high pressure processing in the volume of a process chamber. Various containment apparatus and pressure relief architectures are also described herein to enable safe and efficient operation of apparatus during high pressure processing.

While the foregoing is directed to embodiments of the present disclosure, other and further embodiments of the disclosure may be devised without departing from the basic scope thereof, and the scope thereof is determined by the claims that follow.

What is claimed is:

1. A high pressure processing apparatus, comprising:
a first chamber body defining a first volume therein;
a second chamber body disposed within the first volume, the second chamber body defining a second volume therein;
a steam delivery module in fluid communication with the second volume via a first conduit, the steam delivery module comprising:
a boiler;
a steam reservoir;
a second conduit extending between and in fluid communication with the boiler and the steam reservoir; and
a flow regulator disposed on the second conduit between the boiler and the steam reservoir.

2. The apparatus of claim 1, wherein the boiler and the steam reservoir are fabricated from a nickel containing steel alloy.

3. The apparatus of claim 2, wherein the nickel containing steel alloy comprises molybdenum.

4. The apparatus of claim 3, wherein the nickel containing steel alloy comprises chromium.

5. The apparatus of claim 1, wherein the boiler and the steam reservoir are operable at temperatures greater than about 350° C.

6. The apparatus of claim 5, wherein the boiler and the steam reservoir are operable at pressures greater than about 50 bar.

7. The apparatus of claim 1, further comprising:
an enclosure containing the boiler and the steam reservoir therein.

8. The apparatus of claim 1, further comprising:
a first valve disposed on the first conduit; and
a second valve disposed on the first conduit between the first valve and the first chamber body.

9. The apparatus of claim 8, wherein the first conduit is disposed within a heater jacket, the heater jacket being operable to maintain a temperature of the first conduit at a temperature greater than about 350° C.

10. The apparatus of claim 1, wherein the first volume defined by the first chamber body is between about 80 L and about 150 L.

11. The apparatus of claim 10, wherein the second volume defined by the second chamber body is between about 3 L and about 8 L.

12. A high pressure processing apparatus, comprising:
an enclosure defining a volume therein;
a boiler disposed within the volume, the boiler comprising:
a fluid inlet port;
a fluid outlet port; and
an exhaust port;
a steam reservoir disposed within the volume, the steam reservoir comprising:
a fluid inlet port;
a fluid outlet port; and
an exhaust port;
a conduit extending between the boiler fluid outlet port and the steam reservoir inlet port; and
a flow regulator disposed on the conduit between the boiler and the steam reservoir.

13. The apparatus of claim 12, wherein the enclosure further comprises:
a fluid inlet port; and
an exhaust port.

14. The apparatus of claim 12, wherein the boiler and the steam reservoir are fabricated from a nickel containing steel alloy.

15. The apparatus of claim 14, wherein the nickel containing steel alloy comprises molybdenum.

16. The apparatus of claim 15, wherein the nickel containing steel alloy comprises chromium.

17. A high pressure processing apparatus, comprising:
a first chamber body defining a first volume therein;
a first slit valve door coupled to an external surface of the first chamber body;
a second chamber body disposed within the first volume, the second chamber body defining a second volume therein;
a second slit valve door coupled to an interior surface of the second chamber body;
a steam delivery module in fluid communication with the second volume via a first conduit, the steam delivery module comprising:
a boiler fabricated from a nickel containing steel alloy; and
a steam reservoir fabricated from the nickel containing steel alloy.

18. The apparatus of claim 17, further comprising:
a second conduit extending between and in fluid communication with the boiler and the steam reservoir; and
a flow regulator disposed on the second conduit between the boiler and the steam reservoir.

19. The apparatus of claim 18, wherein the boiler further comprises:
a fluid inlet port;
a fluid outlet port; and
an exhaust port.

20. The apparatus of claim 18, wherein the steam reservoir further comprises:
a fluid inlet port;
a fluid outlet port;
a purge gas port; and
an exhaust port.
